(19) United States
(12) Patent Application Publication
(10) Pub. No.: US 2012/0329196 A1
(43) Pub. Date: Dec. 27, 2012

(54) SOLAR CELL PACKAGING PROCESS

(76) Inventor: Chien-Chih HSU, Mingjian Township (TW)

(21) Appl. No.: 13/166,255

(22) Filed: Jun. 22, 2011

(51) Int. Cl. H01L 31/18

(52) U.S. Cl. 438/64; 257/E31.118

(57) ABSTRACT

A solar cell packaging process is disclosed. At first, a solar cell is provided, and at least one liquid packaging material is spray-coated onto a surface of the solar cell by a spray-coating process. A liquid packaging material is directly spread on the surface of the solar cell in at least one covering process. Then, the liquid packaging material is hardened in curing process. Therefore, a packaging layer is formed on the surface of the solar cell to finish the solar cell packaging. By implementing the above packaging process, it ensures there is no over stress applied on the solar cell in the packaging process to avoid generating broken pieces for significantly improving the yield.

### BACKGROUND OF THE INVENTION

1. Field of the Invention

The present invention relates to a solar cell packaging process.

2. Description of the Prior Art

With the coming of the gradual depletion of the petrochemical energy, scientists try very hard to find new alternate energy sources, such as solar energy, wind energy, water energy, geothermal energy, and bioenergy. Among the alternate energy sources, solar energy gets the most attention because it is safe, clean, and easy to be attained, also an endless source. Therefore, solar energy is a target alternate energy to be developed. So far, solar energy is collected and transformed into electrical energy by solar cells. For protecting the solar cells from damaging, the current solar cells are processed by packaging a protecting material such as glass or plastic film on the surfaces of the solar cells.

However, when the protecting materials are applied on the solar cells by press-fitting during the packaging process, broken pieces may be produced easily due to uneven stresses applied onto the solar cells in the packaging process, thus significantly decreasing the production capacity and incurring a high production cost. To avoid the broken pieces produced by the uneven stresses in the press-fitting process, current solar cells usually adopt a flat-sheet package and thus fail to provide much stylish variation to the appearance of the solar cells.

### SUMMARY OF THE INVENTION

An objective of the present invention is to provide a solar cell packaging process by spreading in order to avoid broken pieces and increase the production yield effectively.

To achieve the above objective, the present invention provides a solar cell packaging process. At first, a solar cell is provided, and at least one liquid packaging material is spray-coated onto a surface of the solar cell by a spray-coating process. The liquid packaging material is directly spread on a surface of the solar cell in at least one covering process. Then, the liquid packaging material is hardened in a curing process. Therefore, a packaging layer is formed on the surface of the solar cell to finish packaging the solar cell.

The solar cell packaging process of the present invention simply needs users to provide at least one solar cell and form the packaging layer on the surface of the solar cell in the spreading and curing processes to finish packaging the solar cell. The above packaging process ensures that no over-stress is applied to the solar cell during the packaging process to avoid producing broken pieces and improving the yield significantly.

### BRIEF DESCRIPTION OF THE DRAWINGS

FIG. 1 is the manufacturing flow chart of the preferred embodiment of the present invention;

FIG. 2 is the manufacturing diagram of the preferred embodiment of the present invention;

FIG. 3 is the manufacturing flow chart of the preferred embodiment of the present invention; and

FIG. 4 is the manufacturing diagram of the preferred embodiment of the present invention.

### DETAILED DESCRIPTION OF THE PREFERRED EMBODIMENTS

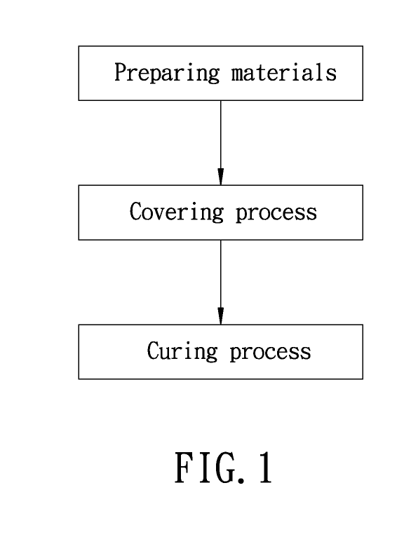

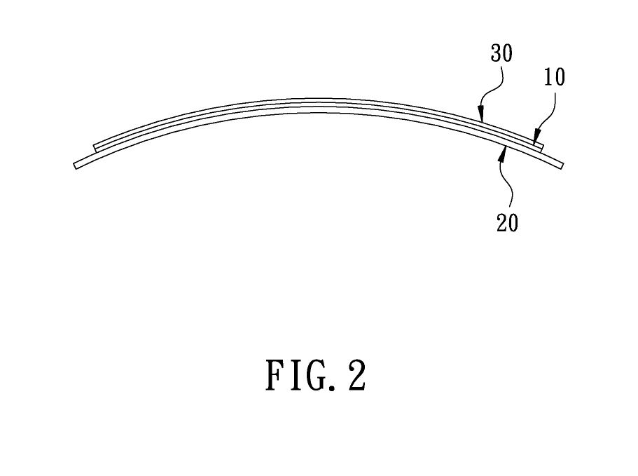

With reference to FIGS. 1 and 2 for the manufacturing flow chart and the diagram of a solar cell packaging process in accordance with a preferred embodiment of the present invention respectively, the solar cell packaging process comprises the following steps:

Preparing materials: At least one solar cell 10 is prepared. A carrier 20 is disposed at a side of the solar cell. The carrier 20 can be one of a glass, acrylics, or printed circuit board. The solar cell 10 can be formed in the same shape of the carrier 20. In this preferred embodiment, the carrier 20 comprises a curved surface, such that the solar cell can be curve-shaped.

Spray-coating process: At least one liquid packaging material is spray-coated onto a surface of the solar cell by a spray-coating process. The liquid packaging material covers the surface of the solar cell 10 directly. The liquid packaging material can be epoxy resin, macromolecular, or polyurethane (PU). The spray-coating process can be performed by spreading, smearing, brushing, or scraping.

Curing process: The corresponding curing method is chosen according to the liquid packaging material. If the liquid packaging material is epoxy resin, the liquid packaging material is hardened by heat baking. If the liquid packaging material is PU, the liquid packaging material is hardened by ultraviolet light and infrared. By performing the curing process, the liquid packaging material can be hardened to form a packaging film 30. Besides, the curing process can be performed by natural drying.

In FIGS. 1 and 2, according to the above packaging process, users simply need to place the solar cell 10 in the carrier 20 and apply the spray-coating and curing processes to the surface of the solar cell 10 to form the packaging film 30 to finish packaging the solar cell 10. Since the spray-coating process is adopted in the packaging process, no over stress is applied onto the solar cell 10. As a result, broken pieces can be avoided, and the production yield can be improved significantly.

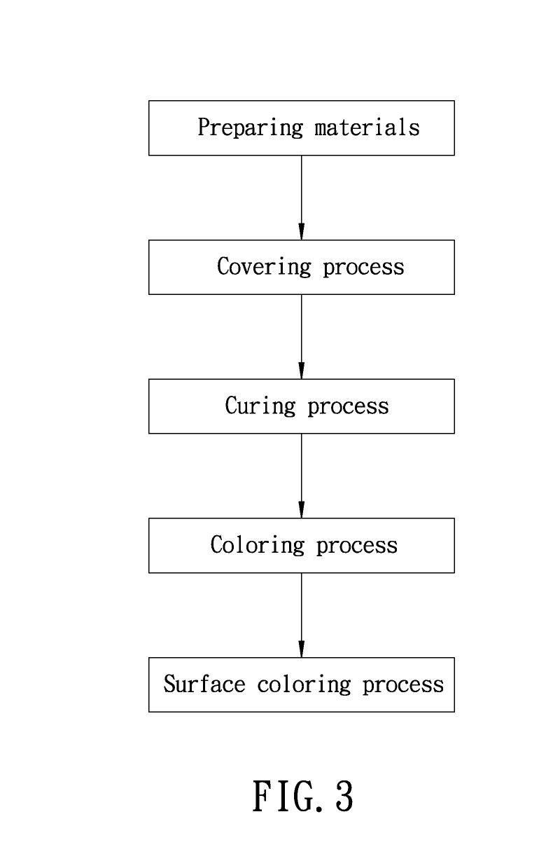

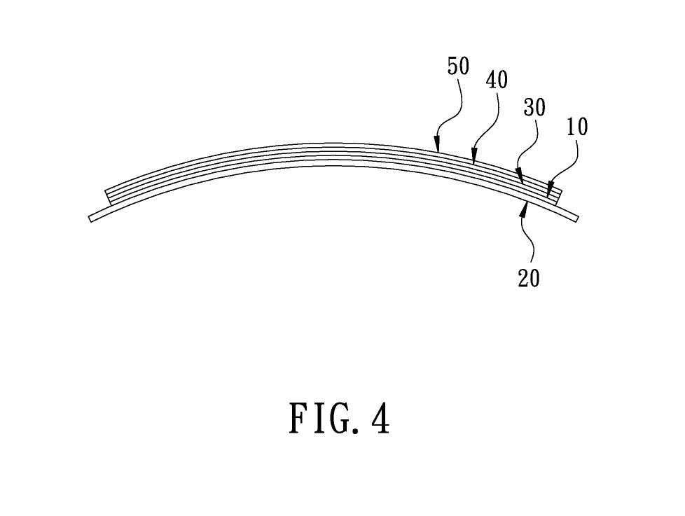

With reference to FIGS. 3 and 4 for the manufacturing flow chart and the diagram of another preferred embodiment of the present invention respectively, the difference between the two packaging processes resides on that after the curing process, a color layer 40 is formed on the solar cell 10 in a coloring process and a functional layer 50 is formed by coating a functional material onto the solar cell 10. The coloring process is performed by a spray coating process or a screen printing process. The color layer 40 is formed by mixing the liquid packaging material with color powders. The liquid packaging material is epoxy resin, a macromolecular material or polyurethane (PU). The functional material is a liquid UV resistant paint or a liquid rain resistant paint. Therefore, the solar cell 10 can be manufactured in different colors and with the UV and rain resistant functions.

It is noteworthy to point out that the spray-coating process spray-coats a plurality of liquid packaging materials onto a surface of the solar cell by a spray-coating method of coating a next layer of liquid packaging material after the preceding layer of liquid packaging material is cured the spray-coating process immediately spray-coats a plurality of liquid packaging materials onto a surface of the solar cell by a spray-coating method of coating a next layer of liquid packaging material before the preceding layer of liquid packaging material is cured, so as to increase the thickness of the packaging layer.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A solar cell packaging process, comprising the steps of:
providing at least a solar cell;
spray coating at least one liquid packaging material onto a surface of the solar cell by a spray-coating process; and
curing the liquid packaging material in a curing process to form a packaging layer on the surface of the solar cell, so as to complete packaging the solar cell.

2. The solar cell packaging process according to claim 1, wherein the covering process comprises spreading, smearing, brushing, scarping, or a combination therefore.

3. The solar cell packaging process according to claim 1, wherein the spray-coating process coats a plurality of liquid packaging materials onto a surface of the solar cell by a spray-coating method of coating a next layer of liquid packaging material after the preceding layer of liquid packaging material is cured.

4. The solar cell packaging process according to claim 1, wherein the spray-coating process immediately coats a plurality of liquid packaging materials onto a surface of the solar cell by a spray-coating method of coating a next layer of liquid packaging material before the preceding layer of liquid packaging material is cured.

5. The solar cell packaging process according to claim 1, further comprising a coloring process after the curing process to form a color layer on the packaging layer.

6. The solar cell packaging process according to claim 5, wherein the coloring process is carried out by a spray coating process or a screen printing process.

7. The solar cell packaging process according to claim 5, wherein the color layer is formed by mixing the liquid packaging material with the color powder uniformly.

8. The solar cell packaging process according to claim 1, wherein the liquid packaging material is one selected from the collection of epoxy resin, a macromolecular material and polyurethane (PU).

9. The solar cell packaging process according to claim 7, wherein the liquid packaging material is one selected from the collection of epoxy resin, a macromolecular material and polyurethane (PU).

10. The solar cell packaging process according to claim 1, wherein the curing process is carried out by heating, ultraviolet light (UV), infrared, or natural drying.

11. The solar cell packaging process according to claim 1, further comprising the step of forming a functional surface by coating a functional material onto the solar cell after the solar cell is processed by the curing process.

12. The solar cell packaging process according to claim 11, wherein the functional material is a UV resistant paint or a rain resistant paint.

13. The solar cell packaging process according to claim 1, wherein the solar cell further comprises a carrier disposed on a side of the solar cell.

14. The solar cell packaging process according to claim 13, wherein the carrier has a curved surface, such that the solar cell is curve-shaped.

15. The solar cell packaging process according to claim 13, wherein the carrier is one selected from the collection of glass, acrylics, and a printed circuit board.
